(19) United States
(12) Patent Application Publication
(10) Pub. No.: US 2026/0107713 A1
(43) Pub. Date: Apr. 16, 2026

(54) ETCHING METHOD

(71) Applicant: ULVAC, INC., Chigasaki-shi (JP)

(72) Inventors: Yamato Osada, Chigasaki-shi (JP); Kazuhiko Tonari, Chigasaki-shi (JP); Youhei Ono, Chigasaki-shi (JP); Atsuaki Hashimoto, Chigasaki-shi (JP)

(21) Appl. No.: 19/346,475

(22) Filed: Sep. 30, 2025

(30) Foreign Application Priority Data
Oct. 10, 2024 (JP) 2024-177868

(51) Int. Cl. H01L 21/311

(52) U.S. Cl. CPC H10P 50/283

(57) ABSTRACT

An etching subject includes a silicon nitride film and a silicon oxide film. A method for selectively etching the silicon nitride film includes etching a surface oxide layer of the silicon nitride film by supplying a hydrogen fluoride gas to the etching subject, and then supplying radicals to the etching subject. The method further includes selectively etching the silicon nitride film by repeating a cycle. The cycle includes supplying the hydrogen fluoride gas to the etching subject, from which the surface oxide layer has been etched, and then supplying radicals to the etching subject. A ratio of an etching amount of the silicon nitride film relative to an etching amount of the silicon oxide film is referred to as a selectivity ratio. A first selectivity in the etching the surface oxide layer is lower than a second selectivity ratio in the selectively etching the silicon nitride film.

### CROSS-REFERENCE TO RELATED APPLICATIONS

This application is based upon and claims the benefit of priority from Japanese Patent Application No. 2024-177868, filed on Oct. 10, 2024, the entire contents of which are incorporated herein by reference.

### TECHNICAL FIELD

The following description relates to an etching method.

### BACKGROUND

An example of a method for selectively etching a silicon nitride film of a wafer, in which the silicon nitride film is adjacent to a silicon oxide film, may include supplying a hydrogen fluoride gas into a processing space, in which the wafer is arranged, and a step of supplying radicals of an inert gas into the processing space. The wafer may be maintained at a relatively low temperature in the step of supplying the hydrogen fluoride gas and the step of supplying the inert gas radicals. This etching method may first supply the hydrogen fluoride gas to the wafer, so that the hydrogen fluoride is adsorbed on the surface of the silicon nitride film. Then, the inert gas radicals are supplied to the wafer, so that the wafer receives an energy that is greater than or equal to an activation energy for etching reaction of hydrogen fluoride with silicon nitride. As a result, etching of the silicon nitride film progresses.

### SUMMARY

In some etching methods, a layer of native oxide may be formed on the surface of the silicon nitride film that is exposed to the outside. In this case, it is difficult to etch the native oxide layer under an etching condition for selectively etching the silicon nitride film. Accordingly, there is a need to remove the native oxide layer formed on the surface of the silicon nitride film.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method for selectively etching a silicon nitride film of an etching subject is provided. The etching subject includes the silicon nitride film and a silicon oxide film. The method includes etching a surface oxide layer of the silicon nitride film by supplying a hydrogen fluoride gas to the etching subject, and supplying radicals to the etching subject after the hydrogen fluoride gas has been supplied. The method further includes selectively etching the silicon nitride film relative to the silicon oxide film by repeating a cycle. The cycle includes supplying the hydrogen fluoride gas to the etching subject, from which the surface oxide layer has been etched, and supplying radicals to the etching subject after the hydrogen fluoride gas has been supplied. A ratio of an etching amount of the silicon nitride film relative to an etching amount of the silicon oxide film is referred to as a selectivity ratio. A first selectivity under a processing condition of the etching the surface oxide layer is lower than a second selectivity ratio under a processing condition of the selectively etching the silicon nitride film.

With this etching method, during etching of the surface oxide layer formed on the surface of the silicon nitride film, the surface oxide layer is etched at the first selectivity ratio that is lower than the second selectivity ratio. This allows for preferential removal of the surface oxide layer before selective etching of the silicon nitride film, without excessively etching the silicon oxide film.

In the above etching method, the etching the surface oxide layer may include repeating a first cycle. The first cycle may include the supplying the hydrogen fluoride gas to the etching subject, and the supplying the radicals to the etching subject after the hydrogen fluoride gas has been supplied.

With this etching method, the surface oxide layer is etched by repeating the first cycle multiple times. This increases the etching accuracy of the surface oxide layer across the entire silicon nitride film, without excessively etching the silicon oxide film.

In the above etching method, at least one of the radicals for the etching the surface oxide layer and the radicals for the selectively etching the silicon nitride film may be oxygen atom-containing radicals. With this etching method, the hydrogen fluoride molecules adsorbed on the etching subject are activated by the oxygen atom-containing radicals having a relatively long radical life.

In the above etching method, the cycle including the supplying the hydrogen fluoride gas to the etching subject, from which the surface oxide layer has been etched, and the supplying radicals to the etching subject after the hydrogen fluoride gas has been supplied may be referred to as a second cycle. In the etching the surface oxide layer, an amount of hydrogen fluoride molecules supplied to the etching subject in a single process may be referred to as a first supply amount. In the selectively etching the silicon nitride film, an amount of the hydrogen fluoride molecules supplied to the etching subject in a single cycle of the second cycle may be referred to as a second supply amount. The first supply amount may be greater than the second supply amount.

With this etching method, the first supply amount is greater than the second supply amount. This facilitates reaction of the activated hydrogen fluoride molecules with the surface oxide layer during etching of the surface oxide layer. As a result, the first selectivity ratio becomes lower than the second selectivity ratio.

The above etching method may further include heating the etching subject to a temperature in a range of 80° C. to 400° C., inclusive, before the etching the surface oxide layer. In the etching the surface oxide layer and the selectively etching the silicon nitride film, the temperature of the etching subject may be maintained in the range of 80° C. to 400° C., inclusive.

With this etching method, the etching subject is heated to a temperature higher than or equal to 80° C. Therefore, the amount of hydrogen fluoride molecules adsorbed across different locations of the etching subject becomes relatively even. Further, the etching subject is heated to a temperature lower than or equal to 400° C., so that the temperature of the etching subject will not become excessively high. This facilitates adsorption of hydrogen fluoride molecules on the etching subject.

In the above etching method, the cycle including the supplying the hydrogen fluoride gas to the etching subject, from which the surface oxide layer has been etched, and the supplying radicals to the etching subject after the hydrogen fluoride gas has been supplied may be referred to as a second cycle. The selectively etching the silicon nitride film may include etching the silicon nitride film by a thickness of greater than 0 nm and less than 5 nm in a single cycle of the second cycle.

With this etching method, the thickness of the silicon nitride film etched in a single cycle is less than 5 nm. Therefore, the etching amount of the silicon nitride film across different locations becomes relatively even.

Other features and aspects will be apparent from the following detailed description, the drawings, and the claims.

### BRIEF DESCRIPTION OF THE DRAWINGS

FIG. 1 is an example of a schematic diagram showing the configuration of an etching device.

FIG. 2 is an example of a schematic diagram showing the configuration of an etching chamber in the etching device shown in FIG. 1.

FIG. 3 is an example of a flowchart illustrating an etching method.

FIG. 4 is an example of a timing diagram illustrating operations of multiple suppliers of the etching device.

FIG. 5 is an example of a diagram illustrating a step of the etching method.

FIG. 6 is an example of a diagram illustrating a step of the etching method.

FIG. 7 is an example of a diagram illustrating a step of the etching method.

FIG. 8 is an example of a diagram illustrating a step of the etching method.

FIG. 9 is an example of a diagram illustrating a step of the etching method.

FIG. 10 is an example of a diagram illustrating a step of the etching method.

FIG. 11 is an example of a diagram illustrating a step of the etching method.

FIG. 12 is an example of a diagram illustrating a step of the etching method.

FIG. 13 is an example of a diagram illustrating a step of the etching method.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

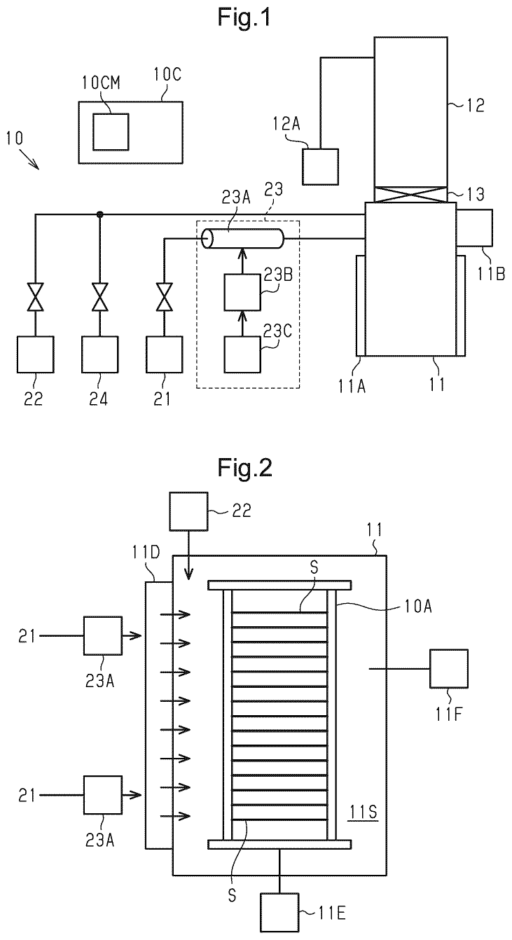

An embodiment of an etching method will now be described with reference to FIGS. 1 to 13.

### Configuration of Etching Device 10

An etching device 10 will be described with reference to FIG. 1.

As shown in FIG. 1, the etching device 10 includes an etching chamber 11, a load lock chamber 12, and a gate valve 13. The etching device 10 includes a radical generation gas supplier 21, a hydrogen fluoride gas supplier (HF gas supplier) 22, a plasma supplier 23, and an inert gas supplier 24. The etching device 10 includes a controller 10C.

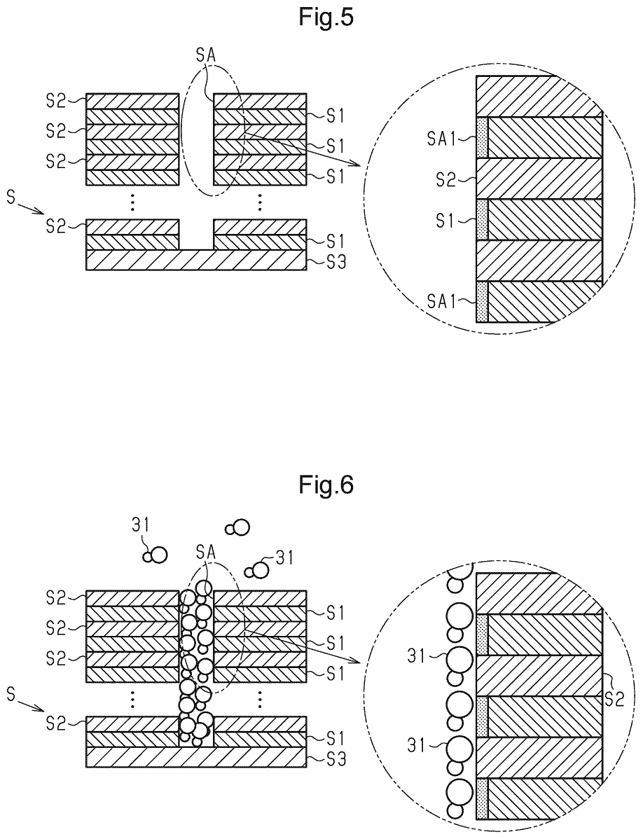

The etching chamber 11 defines a processing space 11S (refer to FIG. 2) in which a substrate S (refer to FIG. 2) is arranged. The substrate S is an example of an etching subject. The substrate S includes a silicon nitride film S1 and a silicon oxide film S2 (refer to FIG. 5). The etching chamber 11 performs etching of the silicon nitride film S1 in the processing space 11S. The load lock chamber 12 loads a pre-etching substrate S into the etching chamber 11. The load lock chamber 12 unloads a post-etching substrate S out of the etching chamber 11.

The gate valve 13 is disposed between the etching chamber 11 and the load lock chamber 12. When the gate valve 13 is open, the etching chamber 11 is connected to the load lock chamber 12. When the gate valve 13 is closed, the etching chamber 11 is disconnected from the load lock chamber 12.

The load lock chamber 12 is connected to a cooling gas supplier 12A. The cooling gas supplier 12A supplies a cooling gas into the load lock chamber 12. The cooling gas is an inert gas for cooling a post-etching substrate S.

The etching chamber 11 includes a heater 11A and a gas discharger 11B. The heater 11A heats the etching chamber 11 so as to heat the substrate S inside the processing space 11S. The gas discharger 11B reduces the pressure of the etching chamber 11 to a predetermined pressure.

The etching chamber 11 is connected to the HF gas supplier 22 and the plasma supplier 23. The HF gas supplier 22 supplies HF gas into the processing space 11S. The HF gas supplier 22 is configured to supply hydrogen fluoride gas (HF gas) into the processing space 11S at a predetermined flow rate. The HF gas supplier 22 is, for example, a mass flow controller.

The plasma supplier 23 supplies plasma into the processing space 11S so as to supply radicals 33 (refer to FIG. 8) contained in the plasma into the processing space 11S. The plasma supplier 23 includes a discharge tube 23A, a waveguide 23B, and a microwave emitter 23C. The microwave emitter 23C emits microwaves through the waveguide 23B toward the discharge tube 23A. The discharge tube 23A is connected to the radical generation gas supplier 21. The discharge tube 23A has an inner surface formed from an inorganic oxide. The inorganic oxide forming the inner surface of the discharge tube 23A may be a silicon oxide or an aluminum oxide. The discharge tube 23A may be, for example, a quartz tube.

The radical generation gas supplier 21 supplies a radical generation gas 32 that generates the radicals 33 into the discharge tube 23A. The radical generation gas supplier 21 supplies the radical generation gas 32 to the discharge tube 23A at a predetermined flow rate. The radical generation gas supplier 21 is, for example, a mass flow controller.

The radical generation gas 32 may be a gas containing oxygen atoms or a noble gas. The noble gas may be argon (Ar) gas or helium (He) gas. The gas containing oxygen atoms (oxygen atom-containing gas) may be at least one selected from a group consisting of oxygen gas, a nitrogen oxide (NₓO_{y}) gas, and a mixture gas of oxygen gas and hydrogen gas. The nitrogen oxide gas may be at least one selected from a group consisting of nitrogen monoxide (NO) gas, nitrogen dioxide (NO₂) gas, dinitrogen monoxide (N₂O) gas, dinitrogen trioxide (N₂O₃) gas, and dinitrogen pentoxide (N₂O₅) gas.

The plasma supplier 23 irradiates the radical generation gas 32 with microwaves inside the discharge tube 23A, so as to generate plasma inside the discharge tube 23A. The plasma contains the radicals 33 that activate hydrogen fluoride molecules (refer to HF molecules 31 in FIG. 6). The radicals 33 that activate the HF molecules 31 may be oxygen atom-containing radicals, oxygen radicals, or noble gas radicals.

The inert gas supplier 24 supplies an inert gas 35 into the processing space 11S. The inert gas supplier 24 is configured to supply the inert gas 35 into the processing space 11S at a predetermined flow rate. The inert gas supplier 24 is, for example, a mass flow controller. The inert gas 35 may be nitrogen (N₂) gas or argon (Ar) gas. The inert gas supplier 24 may supply the inert gas 35 into the processing space 11S through the same pipe as the HF gas supplier 22. Alternatively, the inert gas supplier 24 may supply the inert gas 35 into the processing space 11S through a separate pipe.

The controller 10C includes memory 10CM. The memory 10CM stores processing conditions for etching the silicon nitride film S1. The processing conditions include the pressure of the etching chamber 11, the temperature of the substrate S, the flow rates of the various gases, and the output of the microwave emitter 23C. The controller 10C controls the heater 11A, the gas discharger 11B, the radical generation gas supplier 21, the HF gas supplier 22, the plasma supplier 23, and the inert gas supplier 24, so that etching conditions conform to the processing conditions.

While the controller 10C is controlling the heater 11A to heat the substrate S, so as to maintain the substrate S at a predetermined temperature included in a range of a first temperature to a second temperature, inclusive, the controller 10C controls the HF gas supplier 22 to supply the HF gas and then controls the plasma supplier 23 to supply the radicals 33.

The controller 10C includes an electronic circuit, such as a central processing unit (CPU), a micro-processing unit (MPU), or the like. The controller 10C includes storage, such as a solid state drive (SSD), a hard disk drive (HDD), or the like. The controller 10C includes memory, such as read-only memory (ROM), random-access memory (RAM), registered memory, or the like. The controller 10C may include an integrated circuit, such as an application-specific integrated circuit (ASIC), a field-programmable gate array (FPGA), or the like. All of the processes executed by the controller 10C may be performed by software included in the controller 10C or a combination of an integrated circuit and software included in the controller 10C.

### Configuration of Etching Chamber 11

As shown in FIG. 2, the etching chamber 11 accommodates a support 10A. The support 10A is configured to support a plurality of substrates S. The substrates S supported by the support 10A are stacked with a gap provided between adjacent ones of the substrates S. As described above, each of the substrates S includes the silicon nitride film S1 and the silicon oxide film S2. An example of the substrate S is disc-shaped.

An example of the substrate S includes a plurality of silicon nitride films S1 and a plurality of silicon oxide films S2 (refer to FIG. 5). In the substrate S, the silicon nitride films S1 and the silicon oxide films S2 are alternately arranged. The substrate S includes a hole SA extending through the silicon nitride films S1 and the silicon oxide films S2. The hole SA is defined by a side wall that includes end surfaces of the silicon nitride films S1 and end surfaces of the silicon oxide films S2. The end surface of each of the silicon nitride films S1 may be oxidized. More specifically, a surface oxide layer SA1 of the silicon nitride film S1 may be located on the end surface of each of the silicon nitride films S1. The surface oxide layer SA1 of the silicon nitride film S1 is formed from at least one of silicon oxide and silicon oxynitride. The surface oxide layer SA1 of the silicon nitride film S1 may be formed from only silicon oxide, only silicon oxynitride, or both silicon oxide and silicon oxynitride.

The etching chamber 11 includes a shower head 11D. The shower head 11D is connected to the discharge tube 23A. The shower head 11D may be connected to any number of discharge tubes 23A. FIG. 2 shows an example in which the shower head 11D is connected to two discharge tubes 23A. The shower head 11D has a plurality of supply ports. The supply ports of the shower head 11D are arranged in a direction in which the substrates S are stacked. The supply ports of the shower head 11D eject the plasma supplied from the discharge tubes 23A toward the substrates S.

The etching chamber 11 includes a rotor 11E. The rotor 11E rotates the support 10A in a circumferential direction of the substrates S. The rotor 11E disperses the plasma, which is ejected from the shower head 11D toward the substrates S, and the HF gas, which is supplied from the HF gas supplier 22 toward the substrates S, in the circumferential direction of the substrates S.

The etching chamber 11 includes a thermometer 11F. The thermometer 11F measures the temperature inside the etching chamber 11 as the temperature of the substrates S. The thermometer 11F is connected to the controller 10C. The temperature measured by the thermometer 11F is input to the controller 10C. The controller 10C controls the heater 11A based on the measurement result from the thermometer 11F.

### Etching Method

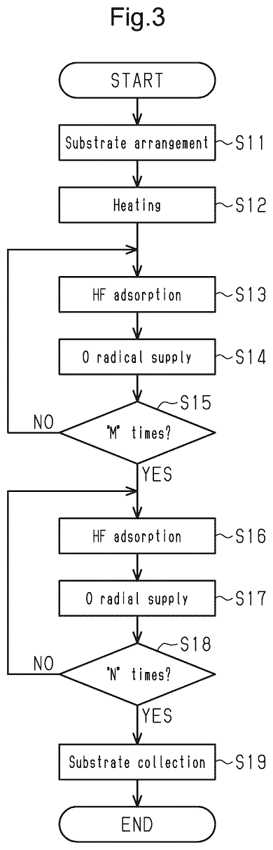

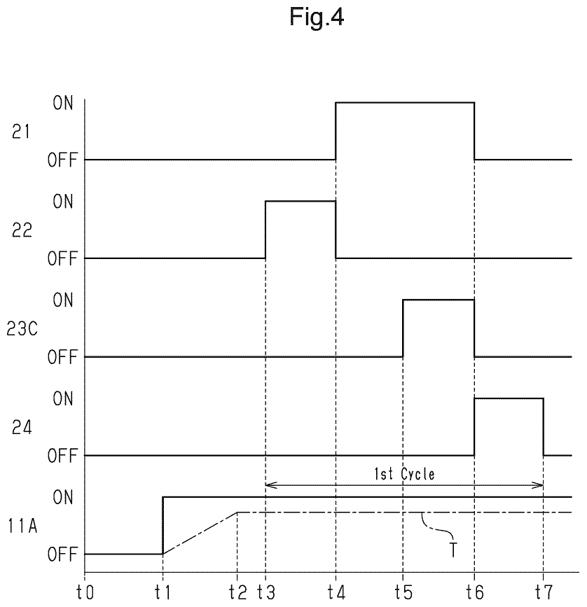

The etching method will now be described with reference to FIGS. 3 and 4.

The etching method is a method for selectively etching the silicon nitride film S1 of the etching subject that includes the silicon nitride film S1 and the silicon oxide film S2. The etching method includes etching the surface oxide layer SA1 formed on the silicon nitride film S1. The etching method includes selectively etching the silicon nitride film S1 relative to the silicon oxide film S2 on the etching subject, from which the surface oxide layer SA1 formed on the silicon nitride film S1 has been etched. A ratio of an etching amount of the silicon nitride film S1 relative to an etching amount of the silicon oxide film S2, that is, a ratio of an etching amount of the silicon nitride film S1 with reference to an etching amount of the silicon oxide film S2, will be referred to as a selectivity ratio. The selectivity ratio under a processing condition for etching the surface oxide layer SA1 will be referred to as a first selectivity ratio. The selectivity ratio under a processing condition for selectively etching the silicon nitride film S1 will be referred to as a second selectivity ratio. The first selectivity ratio is lower than the second selectivity ratio.

The etching the surface oxide layer SA1 includes supplying the HF gas to the etching subject, and supplying the radicals 33 generated from the radical generation gas 32 to the etching subject after the HF gas has been supplied.

The selective etching of the silicon nitride film S1 is performed by repeating a second cycle that includes supplying the HF gas to the etching subject and supplying the radicals 33 generated from the radical generation gas 32 to the etching subject after the HF gas has been supplied. The radical generation gas 32 for the selective etching of the silicon nitride film S1 may be the same as or differ from the radical generation gas 32 for the etching the surface oxide layer SA1.

With the above etching method, during etching of the surface oxide layer SA1 formed on the surface of the silicon nitride film S1, the surface oxide layer SA1 is etched at the first selectivity ratio that is lower than the second selectivity ratio. This allows for removal of the surface oxide layer SA1 before selective etching of the silicon nitride film S1.

FIG. 3 is a flowchart illustrating the etching method. The processing described below may be performed when the controller 10C executes an etching program, which includes the processing conditions stored in the controller 10C.

As shown in FIG. 3, the etching method includes a substrate arrangement step (step S11) and a heating step (step S12). In the substrate arrangement step, a plurality of substrates S are arranged on the support 10A. In this case, the substrates S are placed on the support 10A that is located inside the load lock chamber 12. Then, the support 10A carrying the substrates S is moved from the load lock chamber 12 to the etching chamber 11. After the gate valve 13 is closed, the gas discharger 11B reduces the pressure of the etching chamber 11 to a predetermined pressure.

In the heating step, the heater 11A heats the substrates S. The heater 11A may heat the substrates S to a temperature in a range of 80° C. to 400° C., inclusive, before etching of the surface oxide layer SA1 of the silicon nitride film S1. The temperature of the substrates S may be maintained in the range of 80° C. to 400° C., inclusive, during both etching of the surface oxide layer SA1 and selective etching of the silicon nitride film S1.

When the substrate S is heated to a temperature higher than or equal to 80° C., the amount of HF molecules 31 adsorbed across different locations of the substrate S becomes relatively even. In particular, when the substrate S includes the hole SA extending through the silicon oxide films S2 and the silicon nitride films S1, the HF molecules 31 will not be preferentially adsorbed at the opening of the hole SA. As a result, a relatively even amount of HF molecules 31 may be adsorbed on the side wall of the hole SA with respect to the depth-wise direction of the hole SA. Furthermore, when the substrate S is heated to a temperature lower than or equal to 400° C., the temperature of the substrate S will not become excessively high. This facilitates adsorption of the HF molecules 31 on the substrate S.

Subsequently, etching of the surface oxide layer SA1 formed on the surface of the silicon nitride film S1 is performed. The etching method includes a step of determining whether a first cycle has been repeated a predetermined number of times (step S15). The first cycle includes a step of adsorbing the HF molecules 31 (step S13) and a step of supplying the radicals 33 (step S14). The predetermined number is represented by “M”(2≤M).

In the step of adsorbing the HF molecules 31, the HF gas supplier 22 supplies the HF gas to the etching chamber 11. In the step of supplying the radicals 33, the radical generation gas supplier 21 supplies the radical generation gas 32 to the discharge tube 23A. Then, the microwave emitter 23C emits microwaves toward the discharge tube 23A, so as to generate plasma containing the radicals 33 inside the discharge tube 23A. The plasma supplier 23 supplies the plasma containing the radicals 33 to the etching chamber 11. The radicals 33 may be, for example, oxygen radicals (O radicals).

The first cycle, which includes the step of adsorbing the HF molecules 31 and the step of supplying the radicals 33, is repeated “M” times. The number of times the first cycle is to be repeated may be set in advance.

In this manner, in the etching method, the etching the surface oxide layer SA1 includes repeating the first cycle, which includes the supplying the HF gas to the substrate S, and the supplying the radicals 33 to the substrate S after the HF gas has been supplied. The surface oxide layer SA1 is etched by repeating the first cycle multiple times, thereby increasing the etching accuracy of the surface oxide layer SA1.

Next, etching of the silicon nitride film S1 on the substrate S, from which the surface oxide layer SA1 has been etched, is performed. The etching method includes a step of determining whether the second cycle has been repeated a predetermined number of times (step S18). The second cycle includes a step of adsorbing the HF molecules 31 (step S16) and a step of supplying the radicals 33 (step S17). The predetermined number is represented by “N” (2≤N).

In the step of adsorbing the HF molecules 31, the HF gas supplier 22 supplies the HF gas to the etching chamber 11. In the step of supplying the radicals 33, the radical generation gas supplier 21 supplies the radical generation gas 32 to the discharge tube 23A. Then, the microwave emitter 23C emits microwaves toward the discharge tube 23A, so as to generate plasma containing the radicals 33 inside the discharge tube 23A. The plasma supplier 23 supplies the plasma containing the radicals 33 to the etching chamber 11. The radicals 33 may be, for example, O radicals.

The second cycle, which includes the step of adsorbing the HF molecules 31 and the step of supplying the radicals 33, is repeated “N” times. The number of times the second cycle is to be repeated may be set in advance.

In the selectively etching the silicon nitride film S1, the silicon nitride film S1 may be etched by a thickness of greater than 0 nm and less than 5 nm in a single cycle of the second cycle. When the thickness of the silicon nitride film S1 etched in a single cycle of the second cycle is less than 5 nm, the etching amount of the silicon nitride film S1 across different locations becomes relatively even. In particular, when the substrate S includes the hole SA extending through the silicon oxide films S2 and the silicon nitride films S1, the etching amount of the silicon nitride film S1 with respect to the depth-wise direction of the hole SA becomes relatively even.

The etching method further includes a substrate collection step (step S19). In the substrate collection step, the pressure of the etching chamber 11 is increased to be substantially equal to the pressure of the load lock chamber 12. After the gate valve 13 is opened, the support 10A is moved from the etching chamber 11 to the load lock chamber 12. After the gate valve 13 is closed, the cooling gas supplier 12A supplies the cooling gas to the load lock chamber 12. When the temperature of the substrates S is decreased to a predetermined temperature or lower, the cooling gas supplier 12A stops supplying the cooling gas. Then, the etched substrates S are collected from the load lock chamber 12.

In the etching the surface oxide layer SA1 of the etching method, the amount of HF molecules 31 supplied to the substrate S in a single process will be referred to as a first supply amount. In other words, the amount of HF molecules 31 supplied to the substrate S in a single cycle of the first cycle is the first supply amount. In the selectively etching the silicon nitride film S1, the amount of HF molecules 31 supplied to the etching subject in a single cycle of the second cycle will be referred to as a second supply amount. The first supply amount is greater than the second supply amount.

When the first supply amount is greater than the second supply amount, the activated HF molecules 31 readily react with the silicon oxide film S2. As a result, the first selectivity ratio becomes lower than the second selectivity ratio.

FIG. 4 illustrates an example of a mode in which the controller 10C operates the heater 11A, the radical generation gas supplier 21, the HF gas supplier 22, the microwave emitter 23C, and the inert gas supplier 24. FIG. 4 illustrates the operations of the above components during the heating step (step S12) and a single cycle of the first cycle.

In FIG. 4, a state in which the heater 11A is not heating the substrate S is indicated as “OFF”, and a state in which the heater 11A is heating the substrate S is indicated as “ON”. A state in which the microwave emitter 23C is not emitting microwaves is indicated as “OFF”, and a state in which the microwave emitter 23C is emitting microwaves is indicated as “ON”. States in which the gas suppliers 21, 22, and 24 are not supplying gasses are each indicated as “OFF”, and states in which the gas suppliers 21, 22, and 24 are supplying gases are each indicated as “ON”.

As shown in FIG. 4, when performing etching of the substrate S in the etching chamber 11, the substrate S is first set inside the etching chamber 11 at time t0. At time t1, the controller 10C controls the heater 11A to start heating the substrate S. Accordingly, the temperature T of the substrate S starts to rise. At time t2, the temperature T of the substrate S reaches a predetermined temperature included in a range of 80° C. to 400° C., inclusive.

At time t3, the controller 10C controls the HF gas supplier 22 to start supplying the HF gas.

At time t4, the controller 10C controls the HF gas supplier 22 to stop supplying the HF gas, and controls the radical generation gas supplier 21 to start supplying the radical generation gas 32. At time t5, the controller 10C controls the microwave emitter 23C to start emitting microwaves.

At time t6, the controller 10C controls the radical generation gas supplier 21 to stop supplying the radical generation gas 32, controls the microwave emitter 23C to stop emitting microwaves, and controls the inert gas supplier 24 to start supplying the inert gas 35. At time t7, the controller 10C controls the inert gas supplier 24 to stop supplying the inert gas 35.

In the processing executed by the controller 10C using the etching chamber 11, the step of heating the substrate S is started at time t1 and continued until etching of the substrate S ends. In the processing executed by the controller 10C using the etching chamber 11, the process from time t3 to time t4 corresponds to the step of supplying the HF gas and adsorbing the HF gas on the substrate S. Further, the process from time t4 to time t5 corresponds to the step of supplying the radical generation gas 32. In the processing executed by the controller 10C using the etching chamber 11, the process from time t5 to time t6 corresponds to the step of supplying the radicals 33. Further, the process from time t6 to time t7 corresponds to the step of supplying the inert gas 35.

Thus, the process from time t3 to time t7 corresponds to a single cycle of the first cycle. The controller 10C controls the etching chamber 11 to perform the first cycle multiple times until an amount of the surface oxide layer SA1 etched from the substrate S reaches a predetermined amount. When repeating the first cycle, time t7 in the first cycle performed for the “m−1” h time may coincide with time t3 in the first cycle performed for the “m”th time. Alternatively, a predetermined period may be set between time t7 in the first cycle performed for the “m−1”th time and time t3 in the first cycle performed for the “m”th time.

In a single cycle of the second cycle, the same process from time t3 to time t7 as the first cycle is performed. However, the length from time t3 to time t4 in the first cycle is longer than the length from time t3 to time t4 in the second cycle. In other words, the HF gas is supplied for a longer period of time in the first cycle than the second cycle. Accordingly, the first supply amount in the first cycle becomes greater than the second supply amount in the second cycle. Time t7 in the final cycle of the first cycle may coincide with time t3 in the initial cycle of the second cycle. Alternatively, a predetermined period may be set between time t7 in the final cycle of the first cycle and time t3 in the initial cycle of the second cycle.

### Operation

The operation of the etching method will now be described with reference to FIGS. 5 to 13.

As shown in FIG. 5, the substrate S includes the hole SA extending in the thickness-wise direction. The hole SA extends through two or more silicon nitride films S1 and two or more silicon oxide films S2. The substrate S includes a support base S3. A multilayer film, including the silicon nitride films S1 and the silicon oxide films S2, is formed on the support base S3. Although only a single hole SA is shown in FIGS. 5 to 13 for illustrative purposes, the substrate S includes a plurality of holes SA. The substrate S may be, for example, a substrate for a three-dimensional (3D)-NAND device.

As shown in FIG. 6, in the etching method, the etching device 10 first supplies the HF gas to the substrate S. In this case, some of the HF molecules 31 supplied to the substrate S reach the wall surface of the hole SA, which includes the surface oxide layer SA1. The HF molecules 31 have a relatively high adsorptive property to the substrate S. Therefore, the amount of HF molecules 31 adsorbed at the opening of the hole SA is likely to be greater than the amount of HF molecules 31 adsorbed at the bottom of the hole SA. In this respect, the substrate S is heated to restrict consumption (i.e., adsorption) of the HF molecules 31 at the opening of the hole SA of the substrate S. As a result, some of the HF molecules 31 readily reach the bottom of the hole SA.

In the step of supplying the HF gas to the substrate S, the HF gas may be supplied to the processing space 11S in which the pressure is 500 Pa or higher. When the pressure of the processing space 11S is 500 Pa or higher, the HF molecules 31 are readily adsorbed on the substrate S.

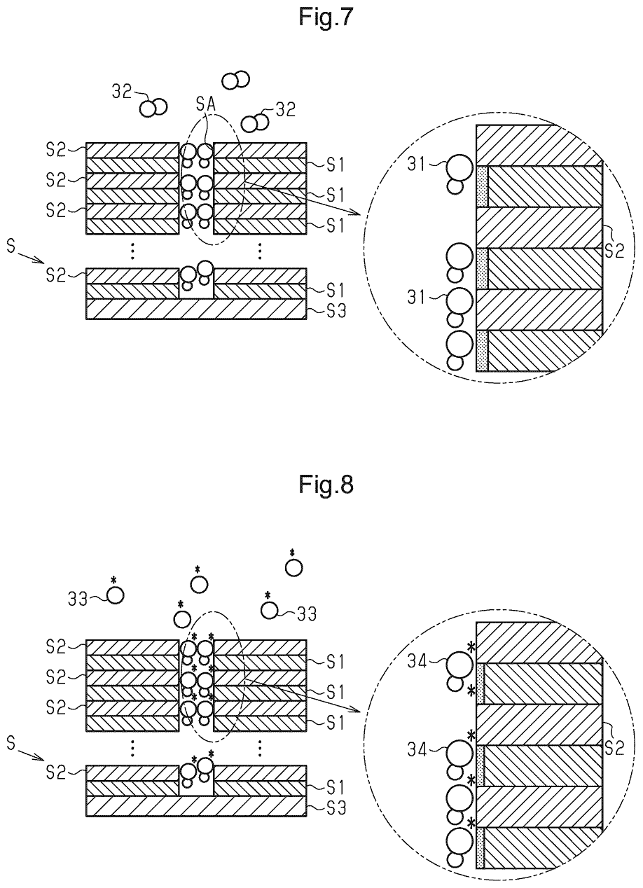

As shown in FIG. 7, after the HF gas has been supplied, the etching device 10 switches the gas being supplied to the substrate S from the HF gas to the radical generation gas 32. In this case, when the radical generation gas 32 is an oxygen atom-containing gas, the radical generation gas 32 has a higher affinity for the silicon oxide film S2 than the HF molecules 31. Therefore, the radical generation gas 32 replaces the HF molecules 31 adsorbed on the silicon oxide film S2, which defines the hole SA, at a higher probability than the HF molecules 31 adsorbed on the surface oxide layer SA1, which is a thin layer of oxide formed on the surface of the silicon nitride film S1. Since the radical generation gas 32 has a relatively low adsorptive property to the substrate S, the radical generation gas 32 is unlikely to remain on the silicon oxide film S2.

As long as the radical generation gas 32 is supplied to the substrate S between the step of supplying the HF gas to the substrate S and the step of supplying the radicals 33 to the substrate S, the flow of the radical generation gas 32 removes at least some of the unnecessary HF molecules 31 located on the substrate S.

As shown in FIG. 8, after the radical generation gas 32 has been supplied, the etching device 10 supplies the radicals 33 generated from the radical generation gas 32 to the substrate S. As a result, an etchant 34 for etching the surface oxide layer SA1 is produced from the HF molecules 31 adsorbed on the silicon nitride film S1, which defines the hole SA, and the radicals 33. As the surface reaction of the HF molecules 31 with the radicals 33 progresses on the substrate S, the surface oxide layer SA1 is etched. The etching of the surface oxide layer SA1 progresses in a direction orthogonal to the depth-wise direction of the hole SA.

During the etching of the surface oxide layer SA1, the surface oxide layer SA1 is etched at the first selectivity ratio that is lower than the second selectivity ratio. As described above, the HF molecules 31 adsorbed on the silicon oxide film S2 have been replaced by the radical generation gas 32 at a higher probability than the HF molecules 31 adsorbed on the surface oxide layer SA1, which is a thin layer of oxide formed on the surface of the silicon nitride film S1. This allows for preferential removal of the surface oxide layer SA1 relative to the silicon oxide film S2, before selective etching of the silicon nitride film S1.

When the radical generation gas 32 is an oxygen atom-containing gas, the oxygen atom-containing radicals (radicals 33) are particularly resistant to deactivation, so that the radicals 33 readily reach the inside of the hole SA. This facilitates etching of the surface oxide layer SA1 inside the hole SA, including at positions near the bottom of the hole SA. Furthermore, when the radicals 33 are generated from a gas containing oxygen atoms, the radicals 33 repair the surface of the silicon oxide film S2 on which the HF molecules 31 are not adsorbed. This further facilitates preferential etching of the surface oxide layer SA1 relative to the silicon oxide film S2.

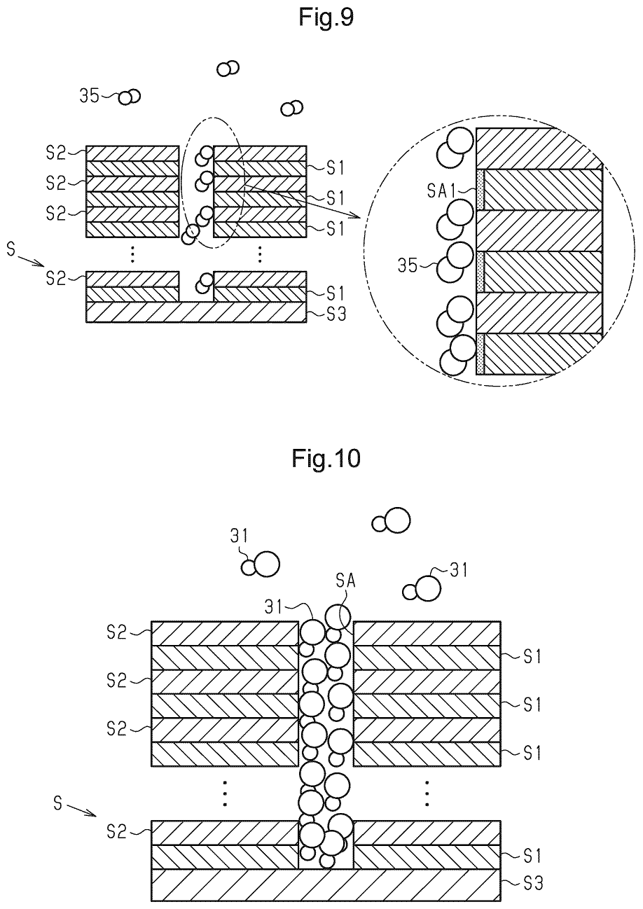

As shown in FIG. 9, after the radicals 33 have been supplied to the substrate S, the etching device 10 switches the gas being supplied to the substrate S from the radicals 33 to the inert gas 35. As described above, the inert gas 35 may be, for example, nitrogen gas. The inert gas 35 supplied to the substrate S reaches the inside of the hole SA, and replaces the HF molecules 31, the radicals 33, and the etchant 34 remaining in the hole SA. When performing etching of the surface oxide layer SA1 multiple times, the temperature of the substrate S is maintained at a predetermined value from the beginning of the initial cycle of the first cycle to the end of the final cycle of the first cycle.

As described above, in the etching method, a single cycle of the first cycle includes supplying the HF gas to the substrate S and supplying the radicals 33 to the substrate S. The etching method may include repeating the first cycle. The first cycle includes supplying the inert gas 35 to the substrate S after supplying the radicals 33 to the substrate S. In this manner, the radicals 33 supplied to the etching subject in the first cycle performed for the “m” h time are unlikely to exist around the substrate S when the first cycle performed for the “m+1”th time is initiated. This avoids etching of the substrate S at locations other than the surface oxide layer SA1 in the first cycle performed for the “m+1”th time.

As shown in FIG. 10, after the surface oxide layer SA1 has been etched, the etching device 10 again supplies the HF gas to the substrate S. The HF molecules 31 supplied to the substrate S reach the wall surface of the hole SA, which is formed by the end surfaces of the silicon nitride films S1 and the end surfaces of the silicon oxide films S2. In this case, the surface oxide layer SA1 has been etched from the end surfaces of the silicon nitride films S1. Since the substrate S is heated to restrict consumption of the HF molecules 31 at the opening of the hole SA of the substrate S, some of the HF molecules 31 readily reach the bottom of the hole SA. In the step of supplying the HF gas to the substrate S, the HF gas may be supplied to the processing space 11S in which the pressure is higher than or equal to that when the HF gas was supplied for etching of the surface oxide layer SA1.

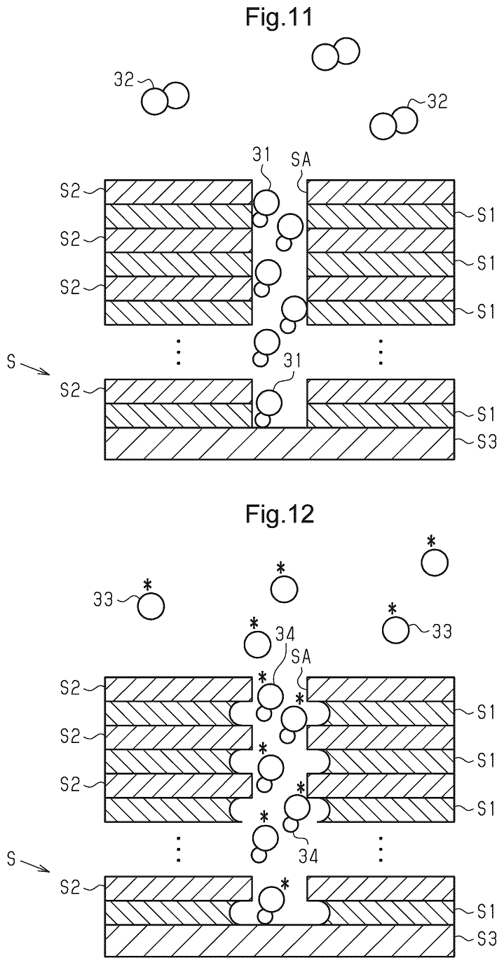

As shown in FIG. 11, after the HF gas has been supplied, the etching device 10 switches the gas being supplied to the substrate S from the HF gas to the radical generation gas 32. In this case, when the radical generation gas 32 is an oxygen atom-containing gas, the radical generation gas 32 has a higher affinity for the silicon oxide film S2 than the HF molecules 31. Therefore, the radical generation gas 32 replaces the HF molecules 31 adsorbed on the silicon oxide film S2, which defines the hole SA, at a higher probability than the HF molecules 31 adsorbed on the silicon nitride film S1.

As shown in FIG. 12, after the radical generation gas 32 has been supplied, the etching device 10 supplies the radicals 33 generated from the radical generation gas 32 to the substrate S. As a result, the etchant 34 for etching the silicon nitride film S1 is produced from the HF molecules 31 adsorbed on the silicon nitride film S1 and the radicals 33. As the surface reaction of the HF molecules 31 with the radicals 33 progresses on the substrate S, the silicon nitride film S1 is etched. The etching of the silicon nitride film S1 progresses in a direction orthogonal to the depth-wise direction of the hole SA.

During the etching of the silicon nitride film S1, the silicon nitride film S1 is etched at the second selectivity ratio that is higher than the first selectivity ratio. In this case, the HF molecules 31 adsorbed on the silicon oxide film S2 have been replaced by the radical generation gas 32 at a higher probability than the HF molecules 31 adsorbed on the silicon nitride film S1. This facilitates selective etching of the silicon nitride film S1. Furthermore, when the radicals 33 are generated from a gas containing oxygen atoms, the radicals 33 repair the surface of the silicon oxide film S2 on which the HF molecules 31 are not adsorbed. This further facilitates preferential etching of the silicon nitride film S1 relative to the silicon oxide film S2.

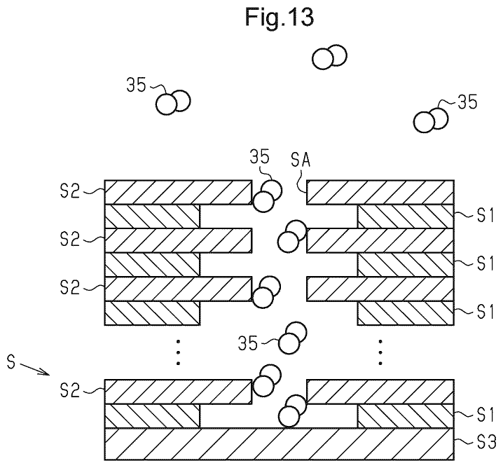

As shown in FIG. 13, after the radicals 33 have been supplied to the substrate S, the etching device 10 switches the gas being supplied to the substrate S from the radicals 33 to the inert gas 35. As described above, the inert gas 35 may be, for example, nitrogen gas. The inert gas 35 supplied to the substrate S reaches the inside of the hole SA, and replaces the HF molecules 31, the radicals 33, and the etchant 34 remaining in the hole SA. The temperature of the substrate S is maintained at a predetermined value from the beginning of the initial cycle of the second cycle to the end of the final cycle of the second cycle. A single cycle of the second cycle includes supplying the HF gas to the substrate S and supplying the radicals 33 to the substrate S. The second cycle includes supplying the inert gas 35 to the substrate S after supplying the radicals 33 to the substrate S. In this manner, the radicals 33 supplied to the etching subject in the second cycle performed for the “n”th time are unlikely to exist around the substrate S when the second cycle performed for the “n+1”th time is initiated. This avoids etching of the substrate S at locations other than the silicon nitride film S1 in the second cycle performed for the “n+1”th time.

The etching method in accordance with the embodiment has the following advantages.
(1) During etching of the surface oxide layer SA1 formed on the surface of the silicon nitride film S1, the surface oxide layer SA1 is etched at the first selectivity ratio that is lower than the second selectivity ratio. This allows for preferential removal of the surface oxide layer SA1 before selective etching of the silicon nitride film S1, without excessively etching the silicon oxide film S2.
(2) The surface oxide layer SA1 is etched by repeating the first cycle multiple times. This increases the etching accuracy of the surface oxide layer SA1 across the entire silicon nitride film S1, without excessively etching the silicon oxide film S2.
(3) When the radicals 33 are oxygen atoms-containing radicals, the HF molecules 31 adsorbed on the etching subject are activated by the oxygen atom-containing radicals having a relatively long radical life.
(4) The first supply amount is greater than the second supply amount. This facilitates reaction of the activated HF molecules 31 and the surface oxide layer SA1 during etching of the surface oxide layer SA1.
(5) The substrate S is heated to a temperature higher than or equal to 80° C. Therefore, the amount of HF molecules 31 adsorbed across different locations of the substrate S becomes relatively even. Further, the substrate S is heated to a temperature lower than or equal to 400° C., so that the temperature of the substrate S will not become excessively high. This facilitates adsorption of the HF molecules 31 on the substrate S.
(6) When the thickness of the silicon nitride film S1 etched in a single cycle of the first cycle is less than 5 nm, the etching amount of the surface oxide layer SA1 across different locations becomes relatively even.

The above embodiment may be modified as described below.

In the etching the surface oxide layer SA1 of the etching method, the temperature of the substrate S may be lower than that in the selectively etching the silicon nitride film S1, such that the first selectivity ratio is lower than the second selectivity ratio.

In the etching the surface oxide layer SA1 of the etching method, the pressure of the etching chamber 11 may be higher than that in the selectively etching the silicon nitride film S1, such that the first selectivity ratio is lower than the second selectivity ratio.

In the etching the surface oxide layer SA1 of the etching method, the flow rate of the HF molecules 31 may be greater than that in the selectively etching the silicon nitride film S1, such that the first selectivity ratio is lower than the second selectivity ratio.

In the etching method, the radical generation gas 32 for etching the surface oxide layer SA1 may differ from the radical generation gas 32 for selectively etching the silicon nitride film S1, such that the first selectivity ratio is lower than the second selectivity ratio.

In the etching method, at least one of the supply period of the HF molecules 31, the temperature of the substrate S, the pressure of the etching chamber 11, the flow rate of the HF molecules 31, and the type of the radical generation gas 32 may be changed, such that the first selectivity ratio is lower than the second selectivity ratio.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A method for selectively etching a silicon nitride film of an etching subject, the etching subject including the silicon nitride film and a silicon oxide film, the method comprising:
etching a surface oxide layer of the silicon nitride film by supplying a hydrogen fluoride gas to the etching subject and supplying one or more radicals to the etching subject after the hydrogen fluoride gas has been supplied; and
selectively etching the silicon nitride film relative to the silicon oxide film by repeating a cycle, the cycle including:
supplying the hydrogen fluoride gas to the etching subject, from which the surface oxide layer has been etched; and
supplying one or more radicals to the etching subject after the hydrogen fluoride gas has been supplied, wherein a ratio of an etching amount of the silicon nitride film relative to an etching amount of the silicon oxide film is referred to as a selectivity ratio, and wherein a first selectivity ratio under a processing condition of the etching the surface oxide layer is lower than a second selectivity ratio under a processing condition of the selectively etching the silicon nitride film.

2. The method according to claim 1, wherein etching the surface oxide layer includes repeating a first cycle, the first cycle including:
the supplying the hydrogen fluoride gas to the etching subject; and
the supplying the radicals to the etching subject after the hydrogen fluoride gas has been supplied.

3. The method according to claim 1, wherein at least one radical of the one or more radicals for the etching the surface oxide layer and at least one radical of the radicals for the selectively etching the silicon nitride film are oxygen atom-containing radicals.

4. The method according to claim 1, wherein:
the cycle including the supplying the hydrogen fluoride gas to the etching subject, from which the surface oxide layer has been etched, and the supplying radicals to the etching subject after the hydrogen fluoride gas has been supplied is referred to as a second cycle;
in the etching the surface oxide layer, an amount of hydrogen fluoride molecules supplied to the etching subject in a single process is referred to as a first supply amount;
in the selectively etching the silicon nitride film, an amount of the hydrogen fluoride molecules supplied to the etching subject in a single cycle of the second cycle is referred to as a second supply amount; and
the first supply amount is greater than the second supply amount.

5. The method according to claim 1, further comprising:
heating the etching subject to a temperature in a range of 80° C. to 400° C., inclusive, before the etching the surface oxide layer, wherein, in the etching the surface oxide layer and the selectively etching the silicon nitride film, the temperature of the etching subject is maintained in the range of 80° C. to 400° C., inclusive.

6. The method according to claim 1, wherein:
the cycle including the supplying the hydrogen fluoride gas to the etching subject, from which the surface oxide layer has been etched, and the supplying radicals to the etching subject after the hydrogen fluoride gas has been supplied is referred to as a second cycle; and
the selectively etching the silicon nitride film includes etching the silicon nitride film by a thickness of greater than 0 nm and less than 5 nm in a single cycle of the second cycle.
